(19) United States
(12) Patent Application Publication
(10) Pub. No.: US 2019/0385915 A1
(43) Pub. Date: Dec. 19, 2019

(54) SEMICONDUCTOR DEVICE AND METHOD FOR MANUFACTURING THE SAME

(71) Applicant: Samsung Electronics Co., Ltd., Suwon-si (KR)

(72) Inventors: Youngmin PARK, Seongnam-si (KR); Kyoung Hwan YEO, Seoul (KR); Jong Mil YOUN, Yongin-si (KR); Hwasung RHEE, Seongnam-si (KR)

(73) Assignee: Samsung Electronics Co., Ltd., Suwon-si (KR)

(21) Appl. No.: 16/249,353

(22) Filed: Jan. 16, 2019

(30) Foreign Application Priority Data
Jun. 18, 2018 (KR) 10-2018-0069768

(51) Int. Cl. H01L 21/8238; H01L 27/092

(52) U.S. Cl. CPC H01L 21/823864; H01L 21/823878; H01L 21/823821; H01L 27/0924

(57) ABSTRACT

A semiconductor device includes a substrate including at least a first region, first active patterns and a first dummy pattern which vertically protrude from the first region, a device isolation layer filling a first trench, a second trench and a third trench of the substrate, and a gate electrode intersecting the first active patterns. The first trench defines the first active patterns on the first region, the second trench defines a first sidewall of the first region, and the third trench defines a second sidewall of the first region, which is opposite to the first sidewall. A sidewall of the first dummy pattern is aligned with the second sidewall of the first region, and a level of a top of the second sidewall of the first region is higher than a level of a top of the first sidewall of the first region.

### CROSS-REFERENCE TO RELATED APPLICATION

This U.S. non-provisional patent application claims priority under 35 U.S.C. § 119 to Korean Patent Application No. 10-2018-0069768, filed on Jun. 18, 2018, in the Korean Intellectual Property Office, the disclosure of which is hereby incorporated by reference in its entirety.

### BACKGROUND

Some example embodiments of the inventive concepts relate to a semiconductor device and a method for manufacturing the same and, more particularly, to a semiconductor device including a field effect transistor and a method for manufacturing the same.

Semiconductor devices are widely used in an electronic industry because of their small sizes, multi-functional characteristics, and/or low manufacturing costs. Semiconductor devices may be categorized as any one of semiconductor memory devices storing logical data, semiconductor logic devices processing logical data, and hybrid semiconductor devices having both the function of the semiconductor memory devices and the function of the semiconductor logic devices. Semiconductor devices with excellent characteristics have been increasingly demanded with the development of the electronics industry. For example, high-reliable, high-speed, and/or multi-functional semiconductor devices have been increasingly demanded. To satisfy these demands, semiconductor devices have become highly integrated and structures of semiconductor devices have become more and more complicated.

### SUMMARY

Some example embodiments of the inventive concepts may provide a semiconductor device including a field effect transistor with improved electrical characteristics, and a method for manufacturing the same.

In some example embodiments, a semiconductor device may include a substrate including at least a first region, first active patterns and a first dummy pattern which vertically protrude from the first region, a device isolation layer filling a first trench, a second trench and a third trench of the substrate, and a gate electrode intersecting the first active patterns. The first trench may define the first active patterns on the first region, the second trench may define a first sidewall of the first region, and the third trench may define a second sidewall of the first region, which is opposite to the first sidewall. A sidewall of the first dummy pattern may be aligned with the second sidewall of the first region, and a level of a top of the second sidewall of the first region may be higher than a level of a top of the first sidewall of the first region.

In some example embodiments, a semiconductor device may include a substrate including a PMOSFET region and an NMOSFET region, and a gate electrode intersecting the PMOSFET region and the NMOSFET region. The PMOSFET region may include first active patterns and a first dummy pattern, and the NMOSFET region may include second active patterns and a second dummy pattern. The first dummy pattern and the second dummy pattern may not be disposed between the first active patterns and the second active patterns. A sidewall of the first dummy pattern may be aligned with a first sidewall of the PMOSFET region, and a sidewall of the second dummy pattern may be aligned with a first sidewall of the NMOSFET region.

In some example embodiments, a method for manufacturing a semiconductor device may include forming a first mold pattern and a second mold pattern on a first region and a second region of a substrate, respectively, forming four first mask patterns on the first region by using the first mold pattern as a mandrel, forming four second mask patterns on the second region by using the second mold pattern as a mandrel, patterning an upper portion of the substrate using the first mask patterns and the second mask patterns as etch masks to form active patterns, forming a PMOSFET region including first active patterns by patterning the first region of the substrate, and forming an NMOSFET region including second active patterns by patterning the second region of the substrate. A distance between the PMOSFET region and the NMOSFET region may be defined by a distance between the first mold pattern and the second mold pattern.

### BRIEF DESCRIPTION OF THE DRAWINGS

Some example embodiments of the inventive concepts will become more apparent in view of the attached drawings and accompanying detailed description.

FIG. 1 is a plan view illustrating a semiconductor device according to some example embodiments of the inventive concepts.

FIGS. 2A, 2B and 2C are cross-sectional views taken along lines A-A′, B-B′, and C-C′ of FIG. 1, respectively.

FIGS. 3, 5, 7, 9, 11, 13, 15, 17 and 19 are plan views illustrating a method for manufacturing a semiconductor device according to some example embodiments of the inventive concepts.

FIGS. 4, 6, 8, 10, 12, 14, 16A, 18A and 20A are cross-sectional views taken along lines A-A′ of FIGS. 3, 5, 7, 9, 11, 13, 15, 17 and 19, respectively.

FIGS. 16B, 18B and 20B are cross-sectional views taken along lines B-B′ of FIGS. 15, 17 and 19, respectively.

FIGS. 16C, 18C and 20C are cross-sectional views taken along lines C-C′ of FIGS. 15, 17 and 19, respectively.

### DETAILED DESCRIPTION

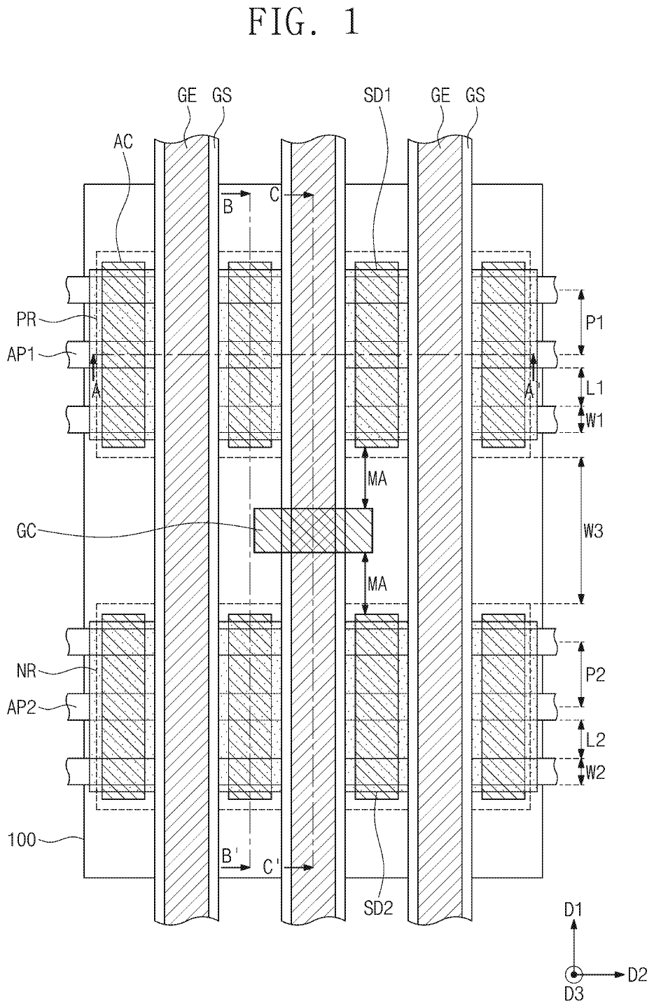

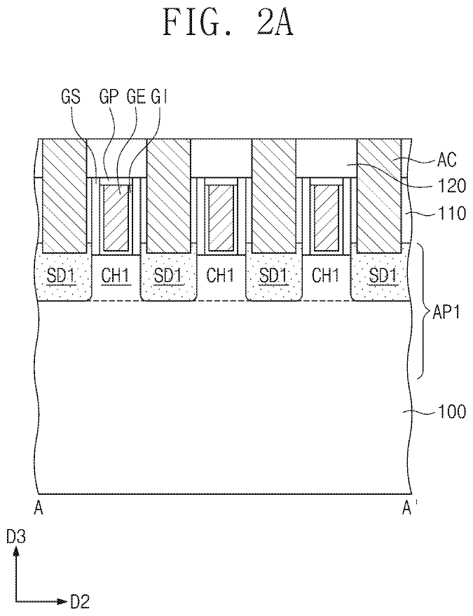

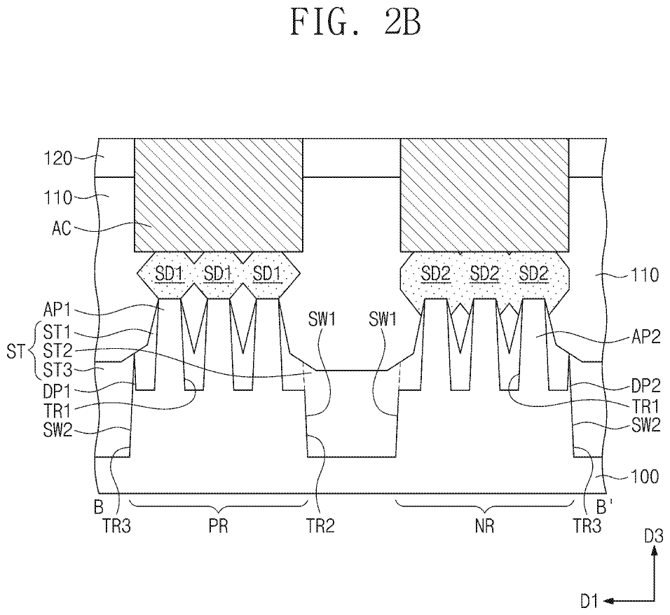

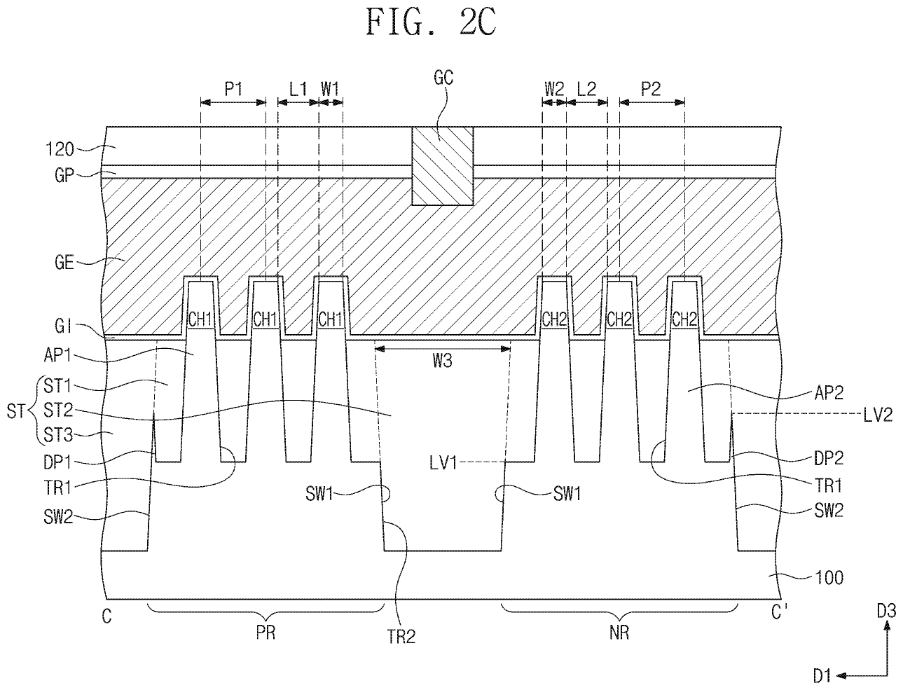

FIG. 1 is a plan view illustrating a semiconductor device according to some example embodiments of the inventive concepts. FIGS. 2A, 2B and 2C are cross-sectional views taken along lines A-A′, B-B′, and C-C′ of FIG. 1, respectively.

Referring to FIGS. 1 and 2A to 2C, a substrate 100 may include a PMOSFET region PR and an NMOSFET region NR. The substrate 100 may be a semiconductor substrate including silicon, germanium, or silicon-germanium, or may be a compound semiconductor substrate. In some example embodiments, the substrate 100 may be a silicon substrate.

In some example embodiments, the PMOSFET region PR and the NMOSFET region NR may be included in a logic cell region on which logic transistors constituting a logic circuit of a semiconductor device are disposed. For example, the logic transistors constituting a processor core or an input/output (I/O) terminal may be disposed on the logic cell region of the substrate 100. Some of the logic transistors may be disposed on the PMOSFET region PR and the NMOSFET region NR.

The PMOSFET region PR and the NMOSFET region NR may be defined by second and third trenches TR2 and TR3 formed in an upper portion of the substrate 100. The second trench TR2 may be disposed between the PMOSFET region PR and the NMOSFET region NR. The second trench TR2 may define a first sidewall SW1 of the PMOSFET region PR and a first sidewall SW1 of the NMOSFET region NR. The third trench TR3 may define a second sidewall SW2 of the PMOSFET region PR and a second sidewall SW2 of the NMOSFET region NR. The second sidewall SW2 of the PMOSFET region PR may be opposite to the first sidewall SW1 of the PMOSFET region PR, and the second sidewall SW2 of the NMOSFET region NR may be opposite to the first sidewall SW1 of the NMOSFET region NR. The first sidewall SW1 of the PMOSFET region PR and the first sidewall SW1 of the NMOSFET region NR may face each other.

The PMOSFET region PR and the NMOSFET region NR may be spaced apart from each other in a first direction D1 with the second trench TR2 interposed therebetween. The PMOSFET region PR and the NMOSFET region NR may extend in a second direction D2 intersecting the first direction D1.

A plurality of active patterns AP1 and AP2 extending in the second direction D2 may be provided on the PMOSFET region PR and the NMOSFET region NR. The active patterns AP1 and AP2 may include first active patterns AP1 on the PMOSFET region PR and second active patterns AP2 on the NMOSFET region NR. The first and second active patterns AP1 and AP2 may be portions of the substrate 100, which vertically protrude. First trenches TR1 may be defined between the first active patterns AP1 adjacent to each other and between the second active patterns AP2 adjacent to each other.

A first dummy pattern DP1 may be provided on the PMOSFET region PR, and a second dummy pattern DP2 may be provided on the NMOSFET region NR. The first dummy pattern DP1 may be adjacent to the second sidewall SW2 of the PMOSFET region PR. A sidewall of the first dummy pattern DP1 may be aligned with the second sidewall SW2 of the PMOSFET region PR. The second dummy pattern DP2 may be adjacent to the second sidewall SW2 of the NMOSFET region NR. A sidewall of the second dummy pattern DP2 may be aligned with the second sidewall SW2 of the NMOSFET region NR. In other words, each of the first and second dummy patterns DP1 and DP2 may be defined by the third trench TR3.

One first dummy pattern DP1 may be disposed on the PMOSFET region PR, and one second dummy pattern DP2 may be disposed on the NMOSFET region NR. The first dummy pattern DP1 may not be adjacent to the first sidewall SW1 of the PMOSFET region PR. The second dummy pattern DP2 may not be adjacent to the first sidewall SW1 of the NMOSFET region NR.

For example, a top of the first sidewall SW1 of the NMOSFET region NR may be disposed at a first level LV1, and a top of the second sidewall SW2 of the NMOSFET region NR may be disposed at a second level LV2 (see FIG. 2C). The second level LV2 may be higher than the first level LV1. The top of the second sidewall SW2 of the NMOSFET region NR may be substantially the same as a top of the second dummy pattern DP2. Similarly, a top of the fist sidewall SW1 of the PMOSFET region PR may be disposed at the first level LV1, and a top of the second sidewall SW2 of the PMOSFET region PR may be disposed at the second level LV2. The top of the second sidewall SW2 of the NMOSFET region NR may be substantially the same as a top of the first dummy pattern DP1.

The top of the first dummy pattern DP1 may be lower than a top of each of the first active patterns AP1. The top of the second dummy pattern DP2 may be lower than a top of each of the second active patterns AP2.

A device isolation layer ST may fill the first to third trenches TR1, TR2 and TR3. The device isolation layer ST may include first, second and third device isolation layers ST1, ST2 and ST3 which fill the first, second and third trenches TR1, TR2 and TR3, respectively. The first to third device isolation layers ST1, ST2 and ST3 may include the same insulating material (e.g., silicon oxide). In other words, the first to third device isolation layers ST1, ST2 and ST3 may be connected to each other as a single unitary body to constitute a single device isolation layer ST. Upper portions of the first and second active patterns AP1 and AP2 may vertically protrude from the first device isolation layer ST1. Each of the upper portions of the first and second active patterns AP1 and AP2 may have a fin shape.

The second and third device isolation layers ST2 and ST3 may be deeper than the first device isolation layer ST1. A level of a bottom surface of each of the second and third device isolation layers ST2 and ST3 may be lower than a level of a bottom surface of the first device isolation layer ST1.

The device isolation layer ST may not cover the upper portions of the first and second active patterns AP1 and AP2. The device isolation layer ST may cover sidewalls of lower portions of the first and second active patterns AP1 and AP2. The device isolation layer ST may completely cover the first and second dummy patterns DP1 and DP2.

The upper portion of each of the first active patterns AP1 may have a first width W1 in the first direction D1. The upper portion of each of the second active patterns AP2 may have a second width W2 in the first direction Dl. The first width W1 may be substantially equal to the second width W2.

A pair of the first active patterns AP1 adjacent to each other may be arranged at a first pitch P1. A pair of the second active patterns AP2 adjacent to each other may be arranged at a second pitch P2. The first pitch P1 may be substantially equal to the second pitch P2. As used herein, the term ‘pitch’ may mean a distance between a center of a first pattern and a center of a second pattern adjacent to the first pattern.

A distance between the upper portions of the pair of first active patterns AP1 may be defined as a first distance L1. A distance between the upper portions of the pair of second active patterns AP2 may be defined as a second distance L2. The first distance L1 may be substantially equal to the second distance L2. The first pitch P1 may be equal to a sum of the first distance L1 and the first width W1. The second pitch P2 may be equal to a sum of the second distance L2 and the second width W2.

An upper portion of the second device isolation layer ST2 under a gate electrode GE (to be described later) may have a third width W3 in the first direction D1. The third width W3 may range from two times to three times the first pitch P1. The third width W3 may range from two times to three times the second pitch P2. In other words, a distance between the PMOSFET region PR and the NMOSFET region NR may range from about two times to about three times the first pitch P1 or the second pitch P2.

First source/drain patterns SD1 may be provided in the upper portions of the first active patterns AP1. The first source/drain patterns SD1 may be dopant regions having a first conductivity type (e.g., a P-type). A first channel region CH1 may be disposed between a pair of the first source/drain patterns SD1. Second source/drain patterns SD2 may be provided in the upper portions of the second active patterns AP2. The second source/drain patterns SD2 may be dopant regions having a second conductivity type (e.g., an N-type), which may be different from the first connectivity type. A second channel region CH2 may be disposed between a pair of the second source/drain patterns SD2.

The first and second source/drain patterns SD1 and SD2 may include epitaxial patterns formed by a selective epitaxial growth (SEG) process. Top surfaces of the first and second source/drain patterns SD1 and SD2 may be disposed at a higher level than top surfaces of the first and second channel regions CH1 and CH2. In some example embodiments, the first source/drain patterns SD1 may include a semiconductor element (e.g., SiGe) of which a lattice constant is greater than that of a semiconductor element of the substrate 100. Thus, the first source/drain patterns SD1 may provide compressive stress to the first channel regions CH1. For example, the second source/drain patterns SD2 may include the same semiconductor element (e.g., silicon) as the substrate 100.

Gate electrodes GE may extend in the first direction D1 to intersect the first and second active patterns AP1 and AP2. The gate electrodes GE may be spaced apart from each other in the second direction D2. The gate electrodes GE may vertically overlap with the first and second channel regions CH1 and CH2. Each of the gate electrodes GE may surround a top surface and both sidewalls of each of the first and second channel regions CH1 and CH2 (see FIG. 2C). For example, the gate electrodes GE may include at least one of a conductive metal nitride (e.g., titanium nitride or tantalum nitride) or a metal material (e.g., titanium, tantalum, tungsten, copper, or aluminum).

A pair of gate spacers GS may be disposed on both sidewalls of each of the gate electrodes GE, respectively. The gate spacers GS may extend along the gate electrodes GE in the first direction D1. Top surfaces of the gate spacers GS may be higher than top surfaces of the gate electrodes GE. The top surfaces of the gate spacers GS may be coplanar with a top surface of a first interlayer insulating layer 110 (to be described later). The gate spacers GS may include at least one of SiCN, SiCON, or SiN. In some example embodiments, each of the gate spacers GS may have a multi-layered structure formed of at least two of SiCN, SiCON, or SiN.

Gate dielectric patterns GI may be disposed between the gate electrodes GE and the active patterns AP1 and AP2. Each of the gate dielectric patterns GI may extend along a bottom surface of each of the gate electrodes GE. Each of the gate dielectric patterns GI may cover the top surface and both sidewalls of each of the first and second channel regions CH1 and CH2. The gate dielectric patterns GI may include a high-k dielectric material. For example, the high-k dielectric material may include at least one of hafnium oxide, hafnium-silicon oxide, lanthanum oxide, zirconium oxide, zirconium-silicon oxide, tantalum oxide, titanium oxide, barium-strontium-titanium oxide, barium-titanium oxide, strontium-titanium oxide, lithium oxide, aluminum oxide, lead-scandium-tantalum oxide, or lead-zinc niobate.

A gate capping pattern GP may be provided on each of the gate electrodes GE. The gate capping patterns GP may extend along the gate electrodes GE in the first direction D1. The gate capping patterns GP may include a material having an etch selectivity with respect to first and second interlayer insulating layers 110 and 120 (to be described later). For example, the gate capping patterns GP may include at least one of SiON, SiCN, SiCON, or SiN.

A first interlayer insulating layer 110 may be provided on the substrate 100. The first interlayer insulating layer 110 may cover the gate spacers GS and the first and second source/drain patterns SD1 and SD2. The top surface of the first interlayer insulating layer 110 may be substantially coplanar with top surfaces of the gate capping patterns GP and the top surfaces of the gate spacers GS. A second interlayer insulating layer 120 may be disposed on the first interlayer insulating layer 110 and the gate capping patterns GP. For example, each of the first and second interlayer insulating layers 110 and 120 may include a silicon oxide layer.

At least one active contact AC may penetrate the second and first interlayer insulating layers 120 and 110 between a pair of the gate electrodes GE so as to be electrically connected to the first and/or second source/drain patterns SD1 and/or SD2. For example, the active contact AC may include at least one selected from metal materials such as aluminum, copper, tungsten, molybdenum, and cobalt.

Silicide layers (not shown) may be disposed between the active contacts AC and the source/drain patterns SD1 and SD2. The active contacts AC may be electrically connected to the first and second source/drain patterns SD1 and SD2 through the silicide layers. The silicide layers may include a metal silicide and may include at least one of, for example, titanium silicide, tantalum silicide, tungsten silicide, nickel silicide, or a cobalt silicide.

At least one gate contact GC that penetrates the second interlayer insulating layer 120 and the gate capping pattern GP so as to be electrically connected to the gate electrode GE may be disposed on the second device isolation layer ST2 (e.g., above the second device isolation layer ST2 in a third direction D3, and between the PMOSFET region PR and the NMOSFET region NR, as shown in FIG. 2C). The gate contact GC may include the same metal material as the active contact AC.

According to some example embodiments of the inventive concepts, the distance between the PMOSFET region PR and the NMOSFET region NR (e.g., the third width W3 of the second device isolation layer ST2) may range from about two times to about three times the first pitch P1 or the second pitch P2. The distance between the PMOSFET region PR and the NMOSFET region NR may be appropriately adjusted depending on the minimum margin MA between the gate contact GC and the active contact AC. Thus, an integration density of a final semiconductor device may be improved and/or occurrence of a process defect may be reduced or prevented, as compared to conventional semiconductor devices and manufacturing methods.

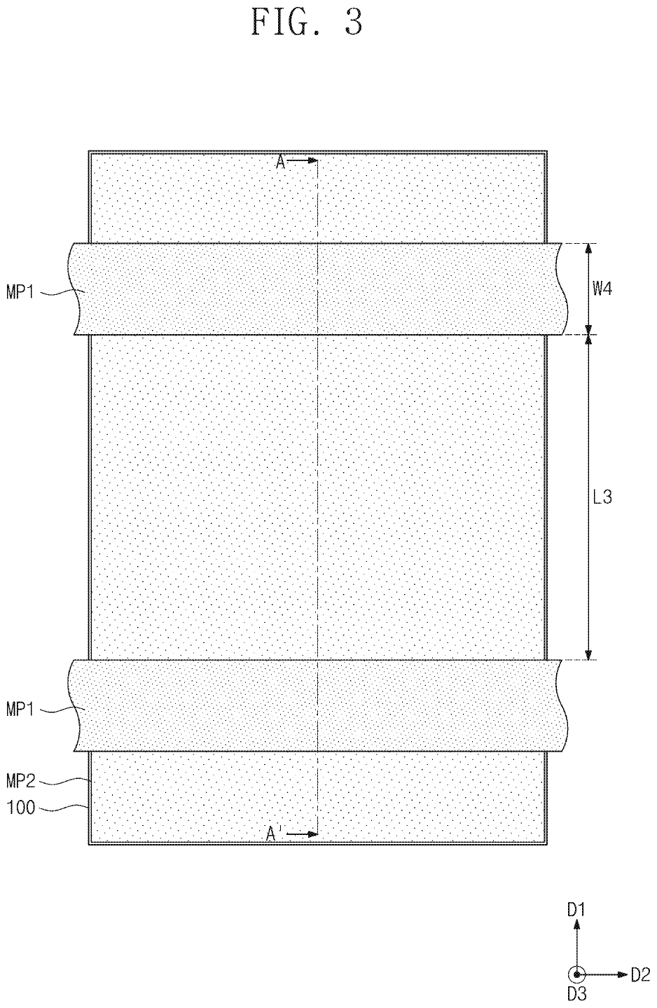

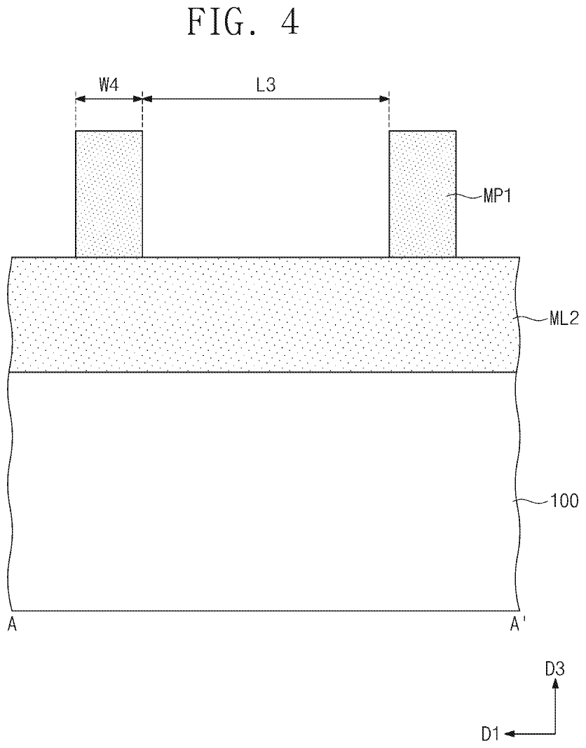

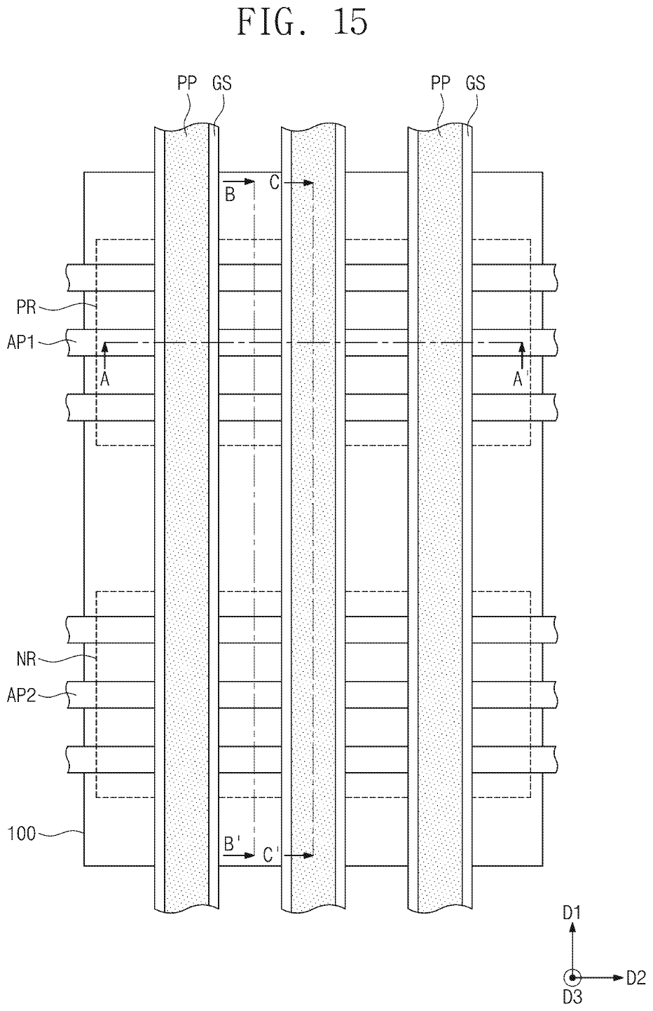

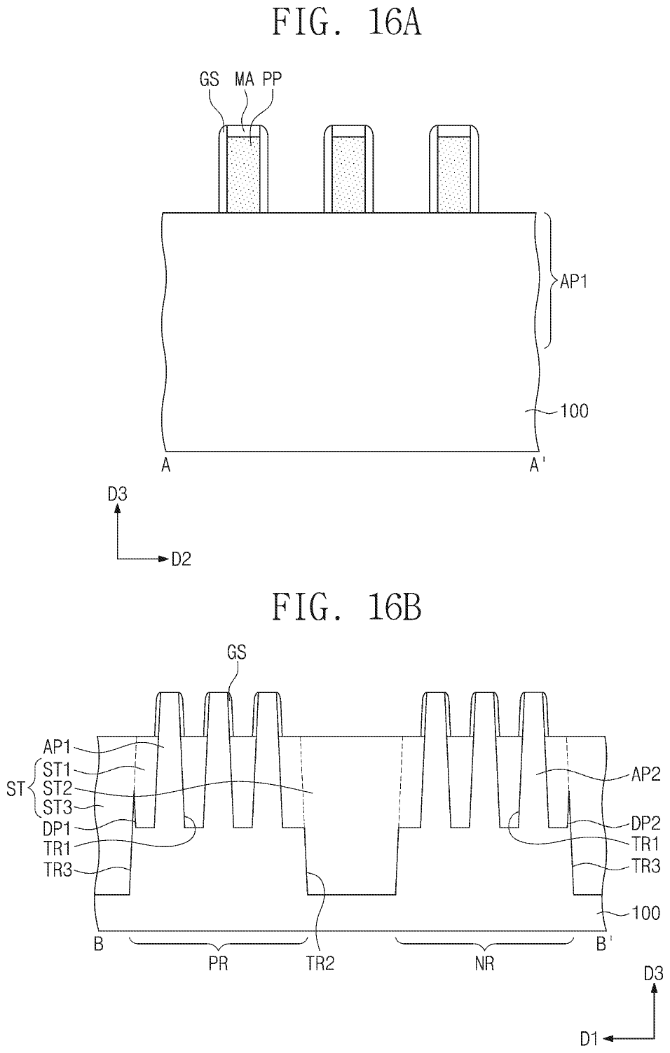

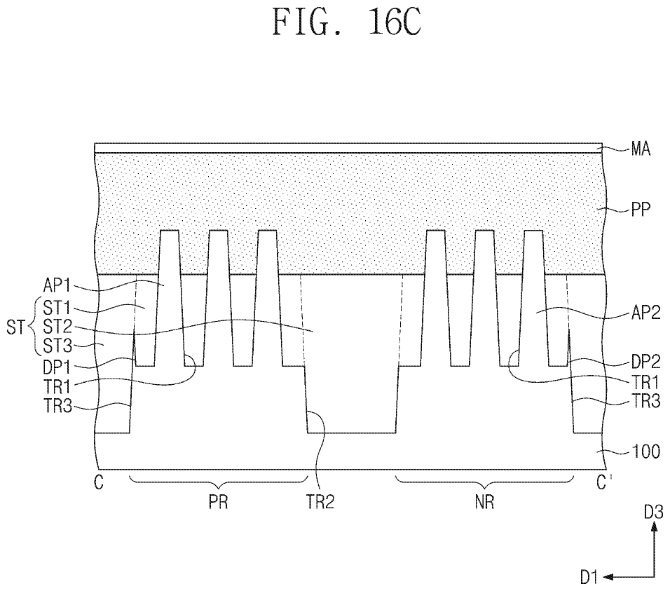

FIGS. 3, 5, 7, 9, 11, 13, 15, 17 and 19 are plan views illustrating a method for manufacturing a semiconductor device according to some example embodiments of the inventive concepts. FIGS. 4, 6, 8, 10, 12, 14, 16A, 18A and 20A are cross-sectional views taken along lines A-A′ of FIGS. 3, 5, 7, 9, 11, 13, 15, 17 and 19, respectively. FIGS. 16B, 18B and 20B are cross-sectional views taken along lines B-B′ of FIGS. 15, 17 and 19, respectively. FIGS. 16C, 18C and 20C are cross-sectional views taken along lines C-C′ of FIGS. 15, 17 and 19, respectively.

Referring to FIGS. 3 and 4, a second mold layer ML2 and first mold patterns MP1 on the second mold layer ML2 may be formed on a substrate 100. The formation of the first mold patterns MP1 may include forming a first mold layer on the second mold layer ML2, and patterning the first mold layer using a photolithography process.

Each of the first mold patterns MP1 may have a line shape extending in the second direction D2. The first mold patterns MP1 may be spaced apart from each other in the first direction D1. A distance between the first mold patterns MP1 may be defined as a third distance L3.

Each of the first mold patterns MP1 may have a fourth width W4. The fourth width W4 may be substantially equal to a sum of the first pitch P1 and the first width W1 described above with reference to FIGS. 1 and 2A to 2C (W4=P1+W1). Similarly, the fourth width W4 may be substantially equal to a sum of the second pitch P2 and the second width W2 described above with reference to FIGS. 1 and 2A to 2C (W4=P2+W2).

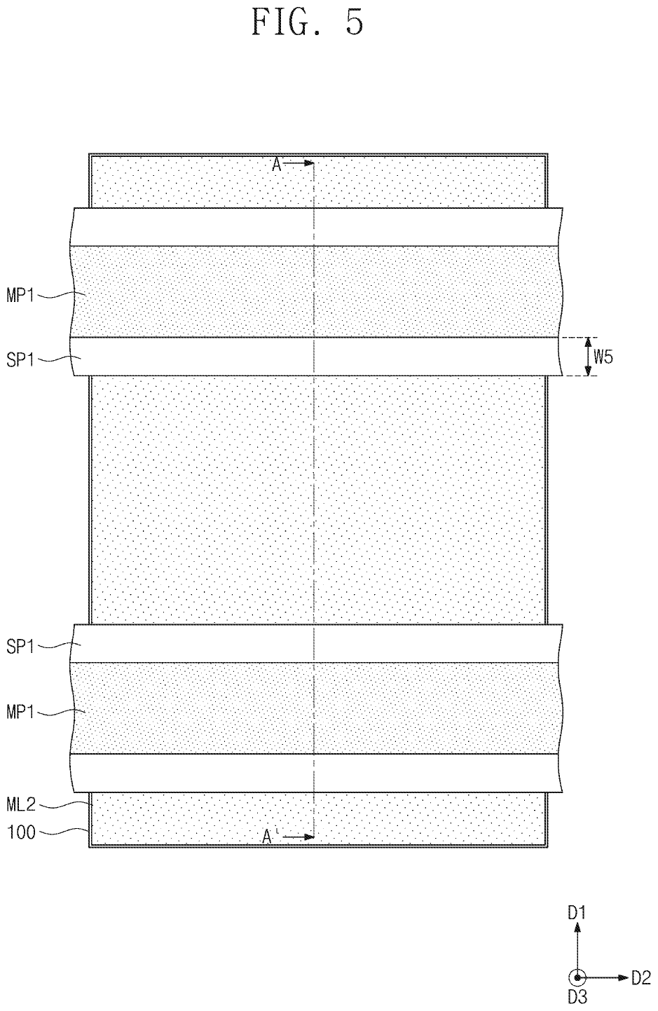

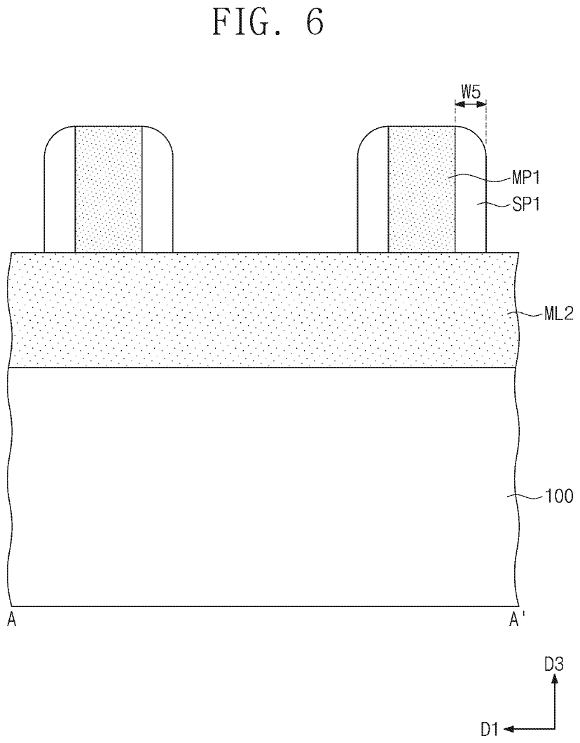

Referring to FIGS. 5 and 6, first spacers SP1 may be formed on both sidewalls of each of the first mold patterns MP1. The first spacers SP1 may extend along the both sidewalls of each of the first mold patterns MP1 in the second direction D2. The formation of the first spacers SP1 may include forming a first spacer layer on an entire top surface of the substrate 100, and anisotropically etching the first spacer layer.

The maximum width of the first spacers SP1 may be defined as a fifth width W5. The first spacer layer may be conformally deposited in such a way that a thickness of the first spacer layers is the fifth width W5. The fifth width W5 may be substantially equal to the first distance L1 described above with reference to FIGS. 1 and 2A to 2C. Similarly, the fifth width W5 may be substantially equal to the second distance L2 described above with reference to FIGS. 1 and 2A to 2C. In other words, the first spacers SP1 may define distances L1 and L2 between active patterns AP1 and AP2 to be formed in a subsequent process.

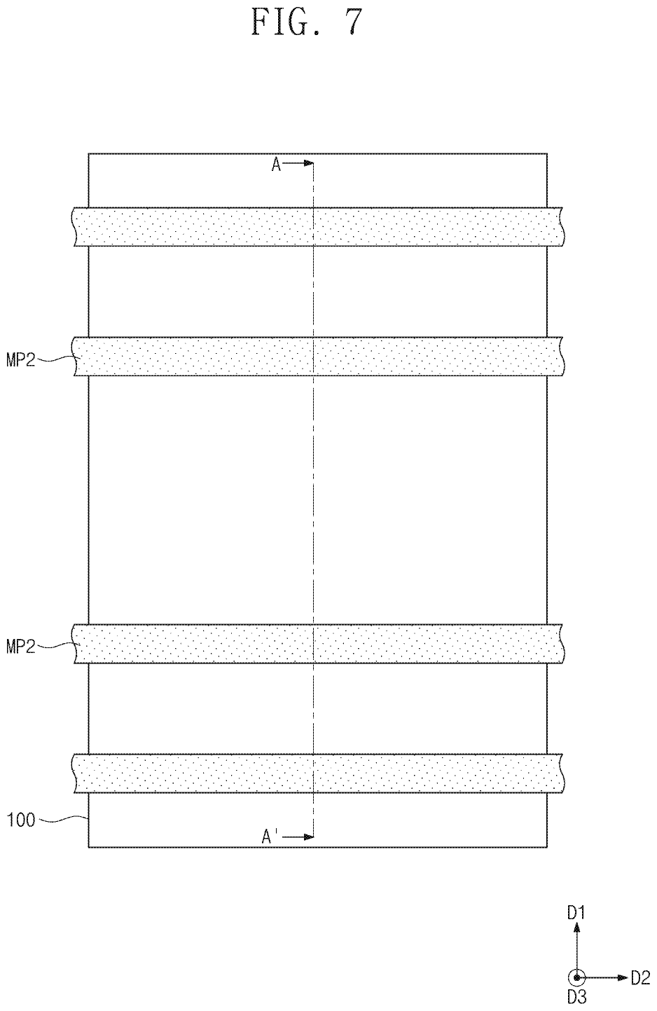

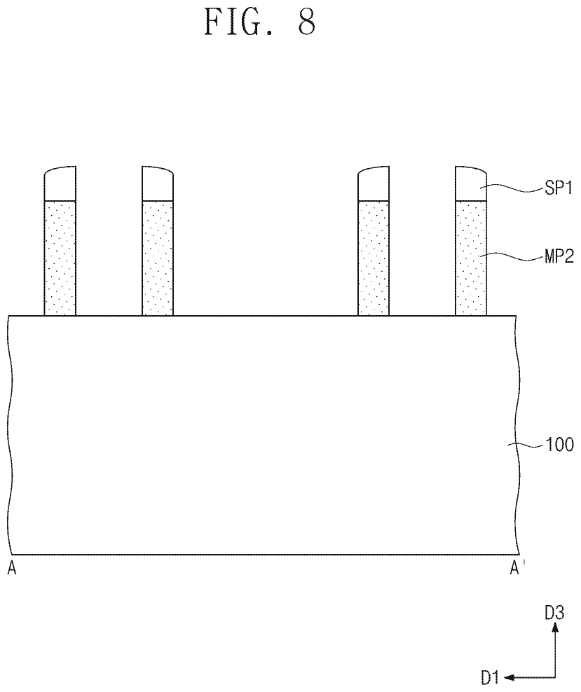

Referring to FIGS. 7 and 8, the first mold patterns MP1 may be selectively removed. The second mold layer ML2 may be patterned using the first spacers SP1 as etch masks to form second mold patterns MP2. Sizes and shapes of the second mold patterns MP2 may be substantially the same as the sizes and shapes of the first spacers SP1.

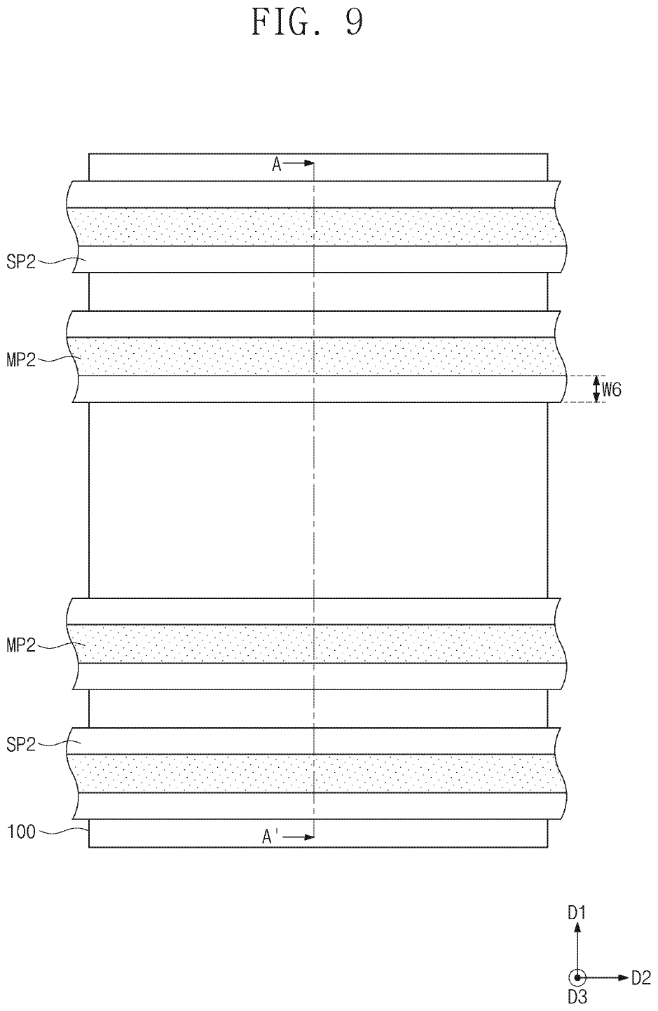

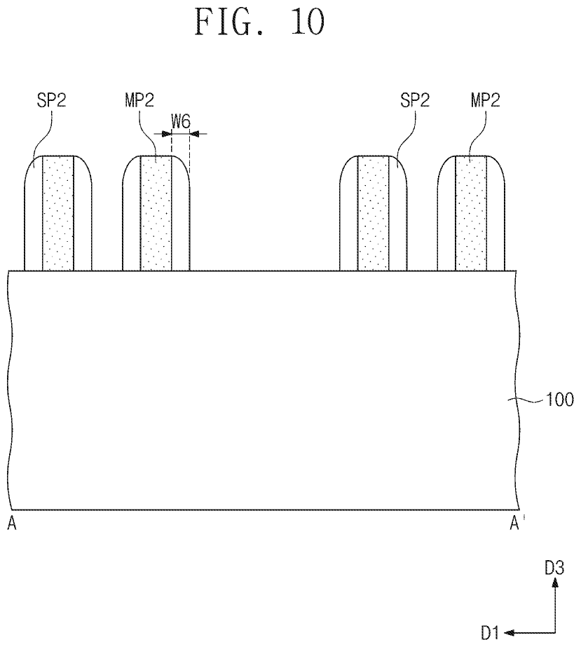

Referring to FIGS. 9 and 10, the first spacers SP1 which remain on the second mold patterns MP2 may be selectively removed. Second spacers SP2 may be formed on both sidewalls of each of the second mold patterns MP2. The second spacers SP2 may extend along the both sidewalls of each of the second mold patterns MP2 in the second direction D2. The formation of the second spacers SP2 may include forming a second spacer layer on an entire top surface of the substrate 100, and anisotropically etching the second spacer layer.

The maximum width of the second spacers SP2 may be defined as a sixth width W6. The second spacer layer may be conformally deposited in such a way that a thickness of the second spacer layer is the sixth width W6. The sixth width W6 may be substantially equal to the first width W1 described above with reference to FIGS. 1 and 2A to 2C. Similarly, the sixth width W6 may be substantially equal to the second width W2 described above with reference to FIGS. 1 and 2A to 2C. In other words, the second spacers SP2 may define first and second active patterns AP1 and AP2 to be formed in a subsequent process.

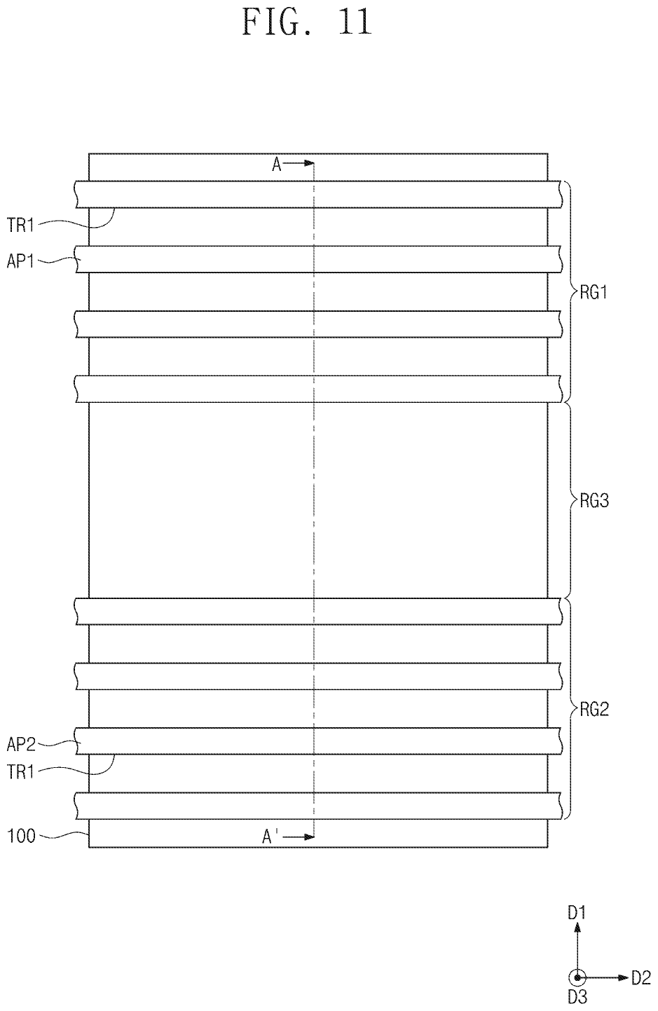

Referring to FIGS. 11 and 12, the second mold patterns MP2 may be selectively removed. The substrate 100 may be patterned using the second spacers SP2 as etch masks to form first and second active patterns AP1 and AP2. First trenches TR1 may be formed between the first active patterns AP1 and between the second active patterns AP2, respectively.

Four first active patterns AP1 may be formed on a first region RG1 of the substrate 100. Four second active patterns AP2 may be formed on a second region RG2 of the substrate 100. Active patterns may not be formed on a third region RG3 between the first and second regions RG1 and RG2.

According to some example embodiments of the inventive concepts, four active patterns may be formed using the first mold pattern MP1 as a mandrel. Four first active patterns AP1 may be formed from one of the first mold patterns MP1 on the first region RG1. Four second active patterns AP2 may be formed from another of the first mold patterns MP1 on the second region RG2. A size (e.g., a length in the first direction D1) of the third region RG3 may be defined by the third distance L3 between the first mold patterns MP1.

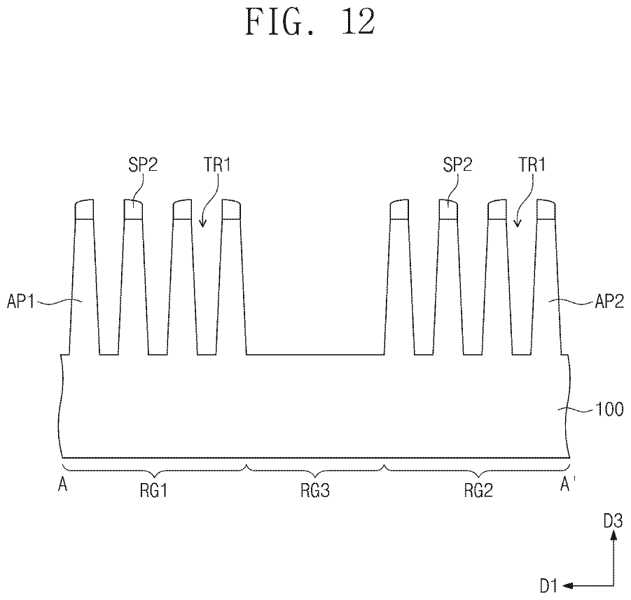

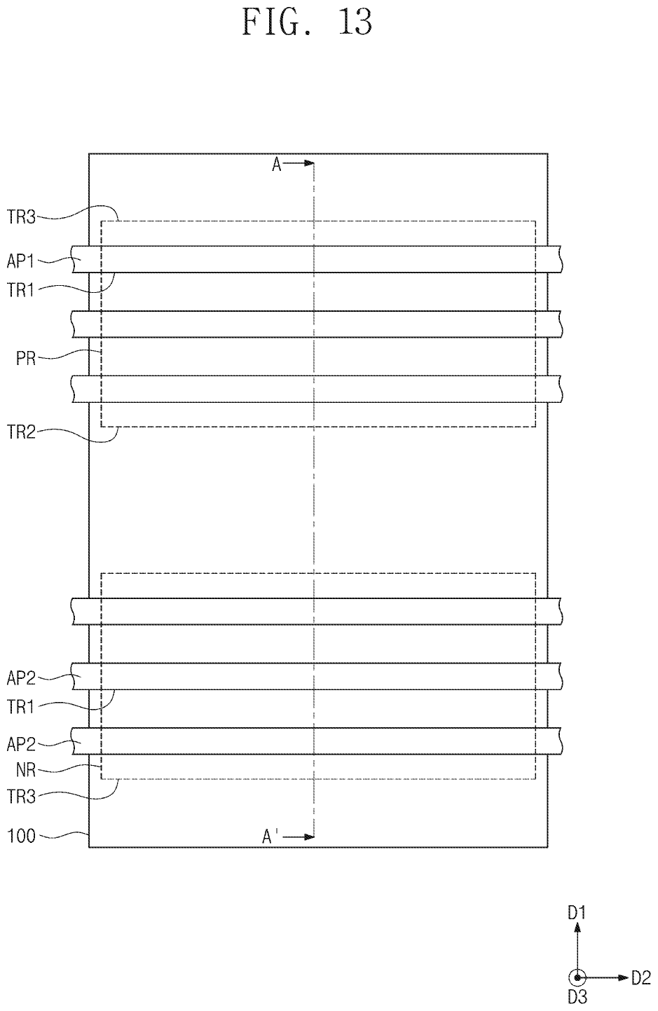

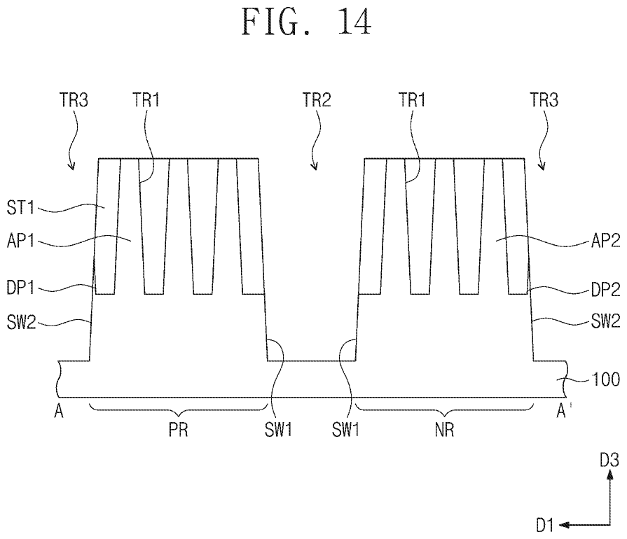

Referring to FIGS. 13 and 14, a first device isolation layer ST1 may be formed on the substrate 100 to fill the first trenches TR1. The first device isolation layer ST1 may include an insulating material such as a silicon oxide layer. A planarization process may be performed on the first device isolation layer ST1 until top surfaces of the first and second active patterns AP1 and AP2 are exposed.

The first device isolation layer ST1 and the substrate 100 may be patterned to form a second trench TR2 and a third trench TR3. A PMOSFET region PR and an NMOSFET region NR may be defined on the substrate 100 by the second and third trenches TR2 and TR3. The PMOSFET region PR may be formed on the first region RG1 of the substrate 100, and the NMOSFET region NR may be formed on the second region RG2 of the substrate 100. The second trench TR2 may be formed in the third region RG3 of the substrate 100.

The second trench TR2 may define a first sidewall SW1 of the PMOSFET region PR and a first sidewall SW1 of the NMOSFET region NR. The third trench TR3 may define a second sidewall SW2 of the PMOSFET region PR and a second sidewall SW2 of the NMOSFET region NR.

When the third trench TR3 is formed, one of the first active patterns AP1 may be removed while leaving a portion of the one of the first active patterns AP1. The remaining portion of the one of the first active patterns AP1 may be defined as a first dummy pattern DP1. When the third trench TR3 is formed, one of the second active patterns AP2 may be removed while leaving a portion of the one of the second active patterns AP2. The remaining portion of the one of the second active patterns AP2 may be defined as a second dummy pattern DP2. On the other hand, since the active patterns may not be formed on the third region RG3, a dummy pattern may not be formed on the third region RG3 when the second trench TR2 is formed in the third region RG3.

Referring to FIGS. 15 and 16A to 16C, second and third device isolation layers ST2 and ST3 may be formed to fill the second and third trenches TR2 and TR3, respectively. The second and third device isolation layers ST2 and ST3 may include an insulating material such as a silicon oxide layer. The first to third device isolation layers ST1, ST2 and ST3 may constitute one device isolation layer ST.

The device isolation layer ST may be recessed until upper portions of the first and second active patterns AP1 and AP2 are exposed. Thus, the upper portions of the first and second active patterns AP1 and AP2 may vertically protrude from the device isolation layer ST (e.g., in the third direction D3).

Sacrificial patterns PP may be formed to intersect the first and second active patterns AP1 and AP2. The sacrificial patterns PP may have line shapes or bar shapes, which extend in the first direction D1. For example, the formation of the sacrificial patterns PP may include forming a sacrificial layer on an entire top surface of the substrate 100, forming hard mask patterns MA on the sacrificial layer, and patterning the sacrificial layer using the hard mask patterns MA as etch masks. The sacrificial layer may include a poly-silicon layer.

A pair of gate spacers GS may be formed on both sidewalls of each of the sacrificial patterns PP, respectively. The gate spacers GS may also be formed on both sidewalls of each of the first and second active patterns AP1 and AP2. Both sidewalls of each of the first and second active patterns AP1 and AP2 may not be covered by the device isolation layer ST and the sacrificial patterns PP but may be exposed.

The formation of the gate spacers GS may include conformally forming a gate spacer layer on an entire top surface of the substrate 100 and anisotropically etching the gate spacer layer. For example, the gate spacer layer may include at least one of SiCN, SiCON, or SiN. In some example embodiments, the gate spacer layer may be formed of a multi-layer including at least two of SiCN, SiCON, or SiN.

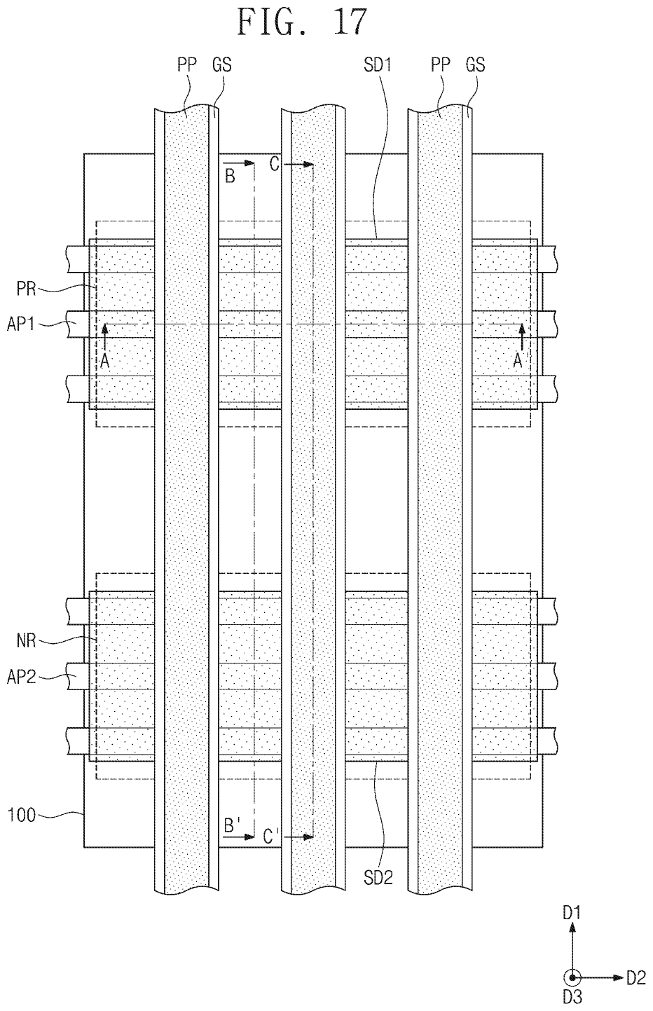

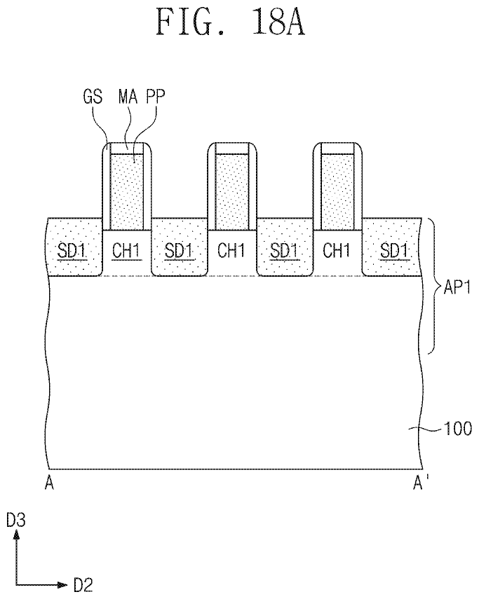

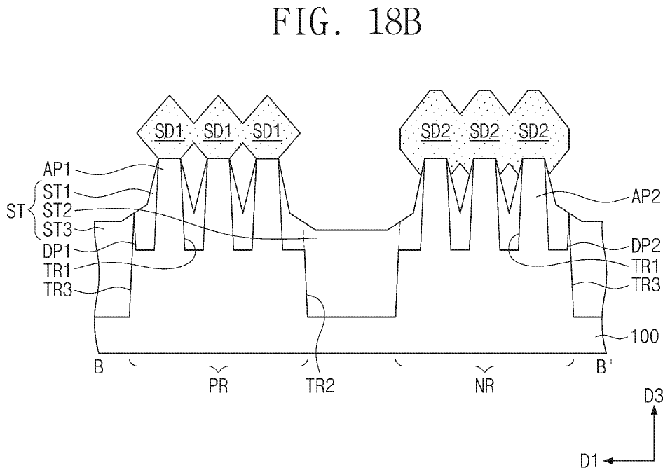

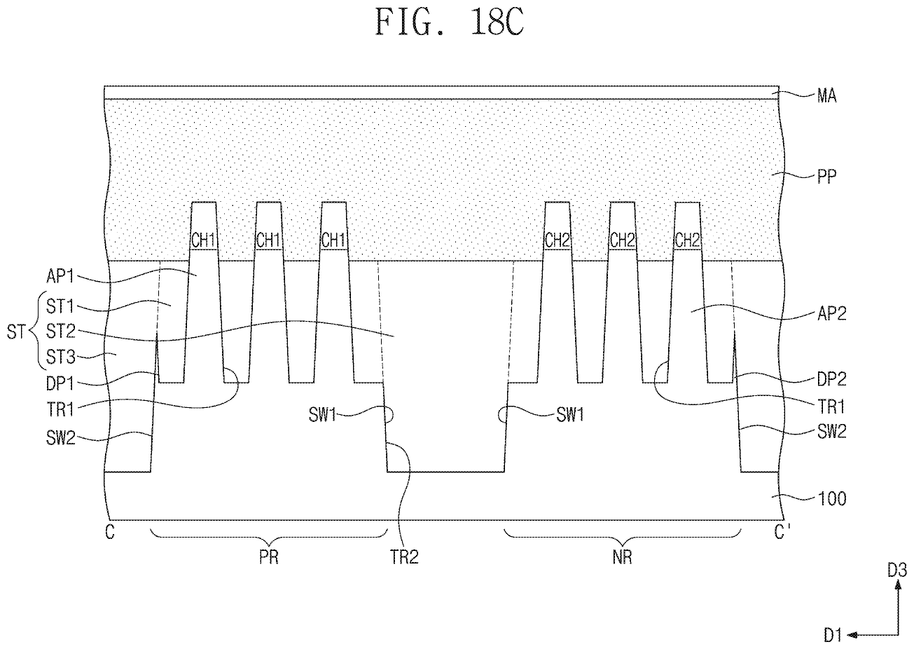

Referring to FIGS. 17 and 18A to 18C, first source/drain patterns SD1 may be formed in the upper portion of each of the first active patterns AP1. A pair of the first source/drain patterns SD1 may be formed at both sides of each of the sacrificial patterns PP.

In detail, the upper portions of the first active patterns AP1 may be etched using the hard mask patterns MA and the gate spacers GS as etch masks to form first recess regions. The gate spacers GS on both sidewalls of each of the first active patterns AP1 may be removed while the upper portions of the first active patterns AP1 are etched. The device isolation layer ST between the first active patterns AP1 may be recessed while the upper portions of the first active patterns AP1 are etched.

The first source/drain patterns SD1 may be formed by performing a selective epitaxial growth (SEG) process using inner surfaces of the first recess regions of the first active patterns AP1 as a seed layer. Since the first source/drain patterns SD1 are formed, the first channel region CH1 may be disposed between a pair of the first source/drain patterns SD1. For example, the SEG process may include a chemical vapor deposition (CVD) process or a molecular beam epitaxy (MBE) process. The first source/drain patterns SD1 may include a semiconductor element (e.g., SiGe) of which a lattice constant is greater than that of a semiconductor element of the substrate 100. In some example embodiments, each of the first source/drain patterns SD1 may be formed of a plurality of stacked semiconductor layers.

In some example embodiments, dopants may be injected in-situ into the first source/drain patterns SD1 during the SEG process for forming the first source/drain patterns SD1. In some other example embodiments, the dopants may be injected or implanted into the first source/drain patterns SD1 after the SEG process for forming the first source/drain patterns SD1. The first source/drain patterns SD1 may be doped with the dopants to have a first conductivity type (e.g., a P-type).

Second source/drain patterns SD2 may be formed in the upper portion of each of the second active patterns AP2. A pair of the second source/drain patterns SD2 may be formed at both sides of each of the sacrificial patterns PP.

In detail, the upper portions of the second active patterns AP2 may be etched using the hard mask patterns MA and the gate spacers GS as etch masks to form second recess regions. The second source/drain patterns SD2 may be formed by performing a SEG process using inner surfaces of the second recess regions of the second active patterns AP2 as a seed layer. Since the second source/drain patterns SD2 are formed, the second channel region CH2 may be disposed between a pair of the second source/drain patterns SD2. For example, the second source/drain patterns SD2 may include the same semiconductor element (e.g., silicon) as the substrate 100. The second source/drain patterns SD2 may be doped with dopants to have a second conductivity type (e.g., an N-type), which may be different from the first connectivity type.

The first source/drain patterns SD1 and the second source/drain patterns SD2 may be sequentially formed by different processes from each other. In other words, the first source/drain patterns SD1 may not be formed simultaneously with the second source/drain patterns SD2.

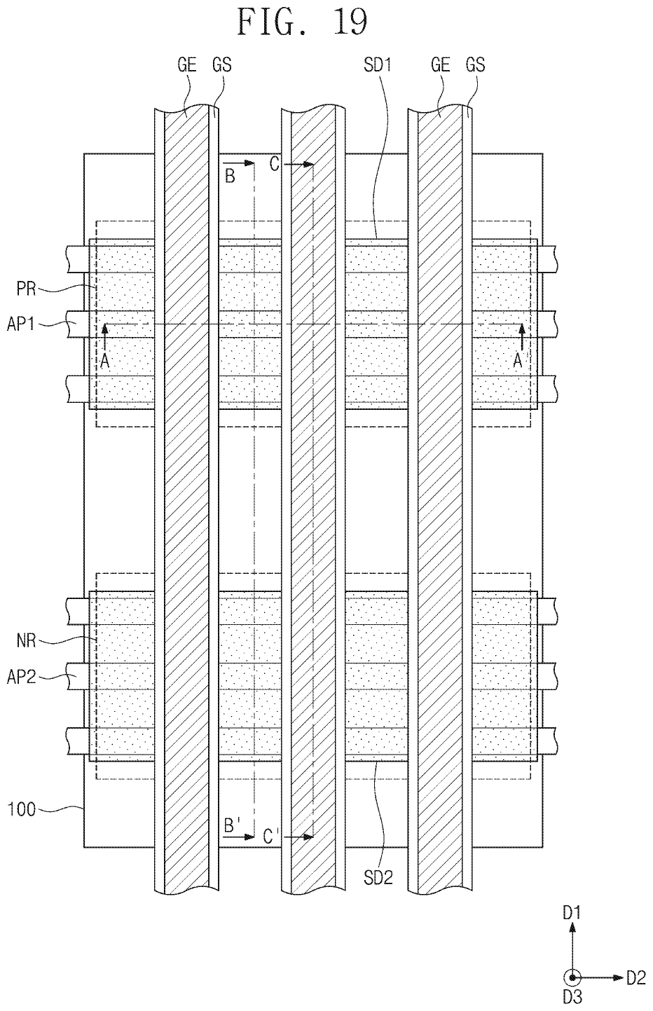

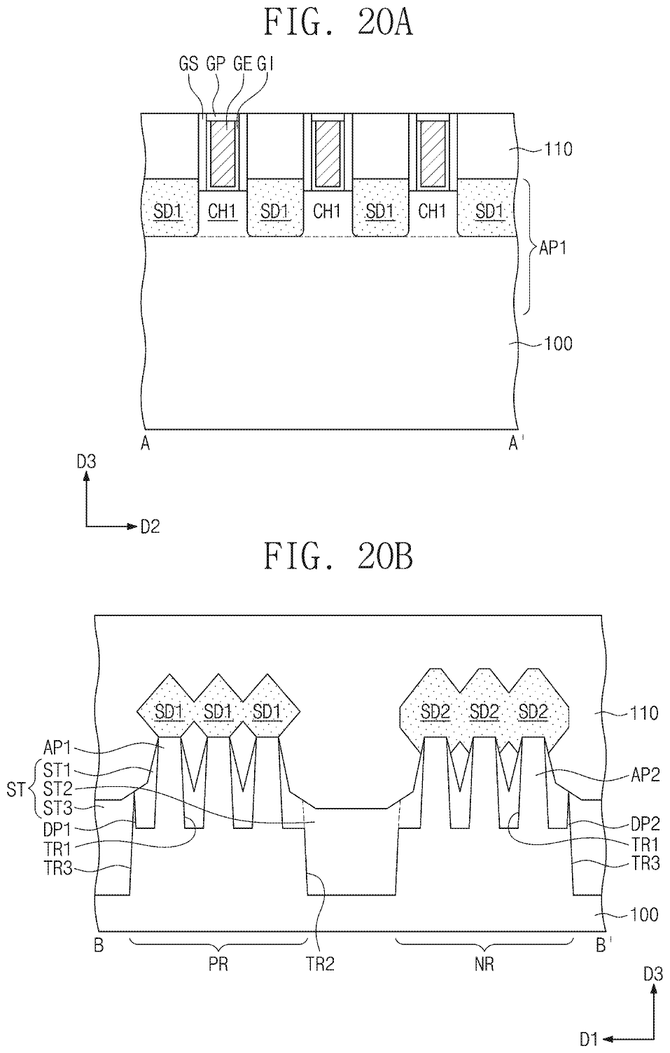

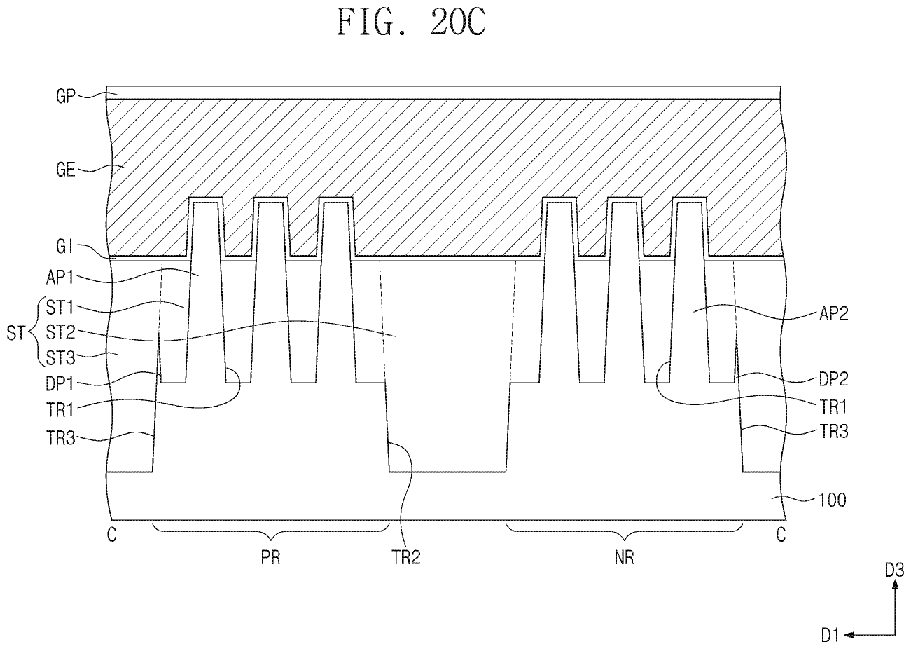

Referring to FIGS. 19 and 20A to 20C, a first interlayer insulating layer 110 may be formed to cover the first and second source/drain patterns SD1 and SD2, the hard mask patterns MA, and the gate spacers GS. For example, the first interlayer insulating layer 110 may include a silicon oxide layer.

The first interlayer insulating layer 110 may be planarized until top surfaces of the sacrificial patterns PP are exposed. The planarization process of the first interlayer insulating layer 110 may be performed using an etch-back process or a chemical mechanical polishing (CMP) process. The hard mask patterns MA may be completely removed during the planarization process. As a result, a top surface of the first interlayer insulating layer 110 may be substantially coplanar with the top surfaces of the sacrificial patterns PP and top surfaces of the gate spacers GS.

The sacrificial patterns PP may be replaced with gate electrodes GE, respectively. In more detail, the exposed sacrificial patterns PP may be selectively removed. Empty spaces may be formed by the removal of the sacrificial patterns PP. A gate dielectric pattern GI, the gate electrode GE and a gate capping pattern GP may be formed in each of the empty spaces. The gate dielectric pattern GI may be conformally formed in the empty space and may not completely fill the empty space. The gate dielectric pattern GI may be formed using an atomic layer deposition (ALD) process or a chemical oxidation process. For example, the gate dielectric pattern GI may include a high-k dielectric material.

A gate electrode layer may be formed to completely fill the empty space, and a planarization process may be performed on the gate electrode layer to form the gate electrode GE. For example, the gate electrode layer may include at least one of a conductive metal nitride or a metal material.

Subsequently, an upper portion of the gate electrode GE may be recessed. The gate capping pattern GP may be formed on the recessed gate electrode GE. For example, the gate capping pattern GP may include at least one of SiON, SiCN, SiCON, or SiN.

Referring again to FIGS. 1 and 2A to 2C, a second interlayer insulating layer 120 may be formed on the first interlayer insulating layer 110. The second interlayer insulating layer 120 may include a silicon oxide layer or a low-k oxide layer. For example, the low-k oxide layer may include a silicon oxide layer doped with carbon, e.g., SiCOH. The second interlayer insulating layer 120 may be formed by a CVD process.

Active contacts AC may be formed in the second and first interlayer insulating layers 120 and 110. The active contacts AC may penetrate the second and first interlayer insulating layers 120 and 110 so as to be electrically connected to the first and second source/drain patterns SD1 and SD2, respectively. A gate contact GC that penetrates the second interlayer insulating layer 120 and the gate capping pattern GP so as to be electrically connected to the gate electrode GE may be formed on the second device isolation layer ST2 (e.g., above the second device isolation layer ST2 in a third direction D3, and between the PMOSFET region PR and the NMOSFET region NR, as shown in FIG. 2C).

For example, the formation of the active contacts AC and the gate contact GC may include performing a patterning process such as a photolithography process to form first openings exposing the first and second source/drain patterns SD1 and SD2, respectively, and a second opening exposing the gate electrode GE, and forming a metal layer filling the first openings and the second opening.

The second opening should be spaced apart from the first openings adjacent thereto by at least the minimum margin MA (or more), due to a limitation of resolution of the photolithography process. However, according to some example embodiments of the inventive concepts, the third distance L3 between the first mold patterns MP1 may be adjusted to adjust a size of a region (e.g., the second device isolation layer ST2) on which the second opening (e.g., the gate contact GC) is formed. In other words, the third distance L3 between the first mold patterns MP1 may be adjusted to secure the minimum margin MA between the second opening (e.g., the gate contact GC) and the first openings (e.g., the active contacts AC) adjacent thereto.

In the semiconductor device and the method for manufacturing the same according to some example embodiments of the inventive concepts, the distance between the PMOSFET region and the NMOSFET region may be appropriately adjusted depending on the minimum margin between the gate contact and the active contact. In the manufacturing method according to some example embodiments of the inventive concepts, the active patterns may be formed using a quadruple patterning technology (QPT) process. At this time, the distance between the PMOSFET region and the NMOSFET region may be adjusted by the distance between the mandrels. As a result, the integration density of the semiconductor device may be improved and/or occurrence of a process defect may be reduced or prevented, as compared to conventional semiconductor devices and manufacturing methods.

While the inventive concepts have been described with reference to some example embodiments, it will be apparent to those skilled in the art that various changes and modifications may be made without departing from the spirits and scopes of the inventive concepts. Therefore, it should be understood that the above example embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A semiconductor device comprising:
a substrate including at least a first region;
first active patterns and a first dummy pattern which vertically protrude from the first region;
a device isolation layer filling a first trench, a second trench and a third trench of the substrate; and
a gate electrode intersecting the first active patterns,
wherein
the first trench defines the first active patterns on the first region,
the second trench defines a first sidewall of the first region,
the third trench defines a second sidewall of the first region, which is opposite to the first sidewall,
a sidewall of the first dummy pattern is aligned with the second sidewall of the first region, and
a level of a top of the second sidewall of the first region is higher than a level of a top of the first sidewall of the first region.

2. The semiconductor device of claim 1, wherein the first dummy pattern is spaced apart from the first sidewall of the first region.

3. The semiconductor device of claim 1, wherein the level of the top of the second sidewall of the first region is substantially the same as a level of a top of the first dummy pattern.

4. The semiconductor device of claim 1, wherein a level of a top of the first dummy pattern is lower than a level of a top of each of the first active patterns.

5. The semiconductor device of claim 1, wherein
an upper portion of each of the first active patterns vertically protrudes from the device isolation layer, and
the device isolation layer covers the first dummy pattern.

6. The semiconductor device of claim 1, further comprising:
second active patterns and a second dummy pattern which vertically protrude from a second region of the substrate,
wherein
the second trench is disposed between the first region and the second region, and
an upper portion of the device isolation layer filling the second trench under the gate electrode has a width ranging from about two times to about three times a first pitch between the first active patterns or a second pitch between the second active patterns.

7. The semiconductor device of claim 6, wherein
the second trench defines a first sidewall of the second region,
the third trench defines a second sidewall of the second region, which is opposite to the first sidewall of the second region,
the first sidewall of the second region faces the first sidewall of the first region, and
a level of a top of the second sidewall of the second region is higher than a level of a top of the first sidewall of the second region.

8. A semiconductor device comprising:
a substrate including a PMOSFET region and an NMOSFET region; and
a gate electrode intersecting the PMOSFET region and the NMOSFET region,
wherein
the PMOSFET region comprises first active patterns and a first dummy pattern,
the NMOSFET region comprises second active patterns and a second dummy pattern,
the first dummy pattern and the second dummy pattern are not disposed between the first active patterns and the second active patterns,
a sidewall of the first dummy pattern is aligned with a first sidewall of the PMOSFET region, and
a sidewall of the second dummy pattern is aligned with a first sidewall of the NMOSFET region.

9. The semiconductor device of claim 8, wherein
a top of the first dummy pattern is lower than a top of each of the first active patterns, and
a top of the second dummy pattern is lower than a top of each of the second active patterns.

10. The semiconductor device of claim 8, further comprising:
a device isolation layer filling a trench between the first active patterns and a trench between the second active patterns on the substrate,
wherein
upper portions of the first active patterns and the second active patterns vertically protrude from the device isolation layer, and
the device isolation layer covers the first dummy pattern and the second dummy pattern.

11. The semiconductor device of claim 8, wherein a distance between the PMOSFET region and the NMOSFET region ranges from about two times to about three times a first pitch between the first active patterns or a second pitch between the second active patterns.

12. The semiconductor device of claim 8, wherein
a second sidewall of the PMOSFET region which is opposite to the first sidewall of the PMOSFET region faces a second sidewall of the NMOSFET region which is opposite to the first sidewall of the NMOSFET region, and
the second sidewall of the PMOSFET region and the second sidewall of the NMOSFET region are disposed between the first active patterns and the second active patterns when viewed in a plan view.

13. A method for manufacturing a semiconductor device, the method comprising:
forming a first mold pattern and a second mold pattern on a first region and a second region of a substrate, respectively;
forming four first mask patterns on the first region by using the first mold pattern as a mandrel;
forming four second mask patterns on the second region by using the second mold pattern as a mandrel;
patterning an upper portion of the substrate using the four first mask patterns and the four second mask patterns as etch masks to form active patterns;
forming a PMOSFET region including first active patterns by patterning the first region of the substrate; and
forming an NMOSFET region including second active patterns by patterning the second region of the substrate,
wherein a distance between the PMOSFET region and the NMOSFET region is defined by a distance between the first mold pattern and the second mold pattern.

14. The method of claim 13, wherein the distance between the PMOSFET region and the NMOSFET region ranges from about two times to about three times a first pitch between the first active patterns or a second pitch between the second active patterns.

15. The method of claim 13, wherein the forming of the PMOSFET region includes partially removing one of the active patterns on the first region to form a first dummy pattern.

16. The method of claim 15, wherein
the forming of the PMOSFET region further includes patterning the first region of the substrate to form a trench defining the PMOSFET region, and
a sidewall of the PMOSFET region and a sidewall of the first dummy pattern are aligned with each other by the trench.

17. The method of claim 13, wherein the forming of the NMOSFET region includes partially removing one of the active patterns on the second region to form a second dummy pattern.

18. The method of claim 13, wherein the forming of the four first mask patterns and the four second mask patterns comprises:
forming first spacers on both sidewalls of each of the first mold pattern and the second mold pattern;
forming two third mold patterns on the first region and two fourth mold patterns on the second region by using the first spacers;
forming second spacers on both sidewalls of each of the two third mold patterns and the two fourth mold patterns; and
forming the four first mask patterns and the four second mask patterns using the second spacers.

19. The method of claim 13, further comprising:
forming a device isolation layer exposing upper portions of the first active patterns and the second active patterns on the substrate;
forming first source/drain patterns and second source/drain patterns in the upper portions of the first active patterns and the second active patterns, respectively; and
forming a gate electrode intersecting the first active patterns and the second active patterns.

20. The method of claim 19, further comprising:
forming an active contact which is disposed on and electrically connected to at least one of the first source/drain patterns and the second source/drain patterns; and
forming a gate contact which is disposed on and electrically connected to the gate electrode between the PMOSFET region and the NMOSFET region,
wherein the distance between the PMOSFET region and the NMOSFET region is adjusted to secure a minimum margin between the active contact and the gate contact.
